(19) United States
(12) Patent Application Publication
(10) Pub. No.: US 2025/0204262 A1
(43) Pub. Date: Jun. 19, 2025

(54) REACTIVE ION BEAM ETCHING

(71) Applicant: Samsung Electronics Co., Ltd., Suwon-si (KR)

(72) Inventors: Kyoungho KWAK, Suwon-si (KR); Songyun Kang, Suwon-si (KR); Taewoo Kim, Suwon-si (KR); Hyungyong Kim, Suwon-si (KR)

(73) Assignee: Samsung Electronics Co., Ltd., Suwon-si (KR)

(21) Appl. No.: 18/742,750

(22) Filed: Jun. 13, 2024

(30) Foreign Application Priority Data
Dec. 15, 2023 (KR) 10-2023-0182550

(51) Int. Cl. H10N 50/01; H10B 61/00

(52) U.S. Cl. CPC H10N 50/01; H10B 61/20

(57) ABSTRACT

An ion beam etching method includes preparing a substrate on which a plurality of magnetic random access memory (MRAM) stacks are provided, performing main etching using ion beam etching such that sidewalls of the plurality of MRAM stacks have a target angle of inclination, and removing a conductive etching by-product redeposited on the sidewalls of the plurality of MRAM stacks during the main etching by performing trim etching using ion beam etching, where the performing the main etching includes performing a first main etching using ion beam etching on the plurality of MRAM stacks at a first incidence angle with respect to an upper surface of the substrate, and after performing the first main etching, performing a second main etching using ion beam etching on the plurality of MRAM stacks at a second incidence angle that is smaller than the first incidence angle.

### CROSS-REFERENCE TO RELATED APPLICATION

This application is based on and claims priority to Korean Patent Application No. 10-2023-0182550, filed on Dec. 15, 2023, in the Korean Intellectual Property Office, the disclosure of which is incorporated herein by reference in its entirety.

### BACKGROUND

Example embodiments of the disclosure related to a reactive ion beam etching method.

Thin film etching technology using an ion beam may tilt an object to be processed, and may obtain a desired sidewall profile using directionality of the ion beam. An ion beam etching process may be employed to etch magnetic random access memory (MRAM) stacks in a MRAM manufacturing process. However, when a processed product such as an MRAM stack contains a conductive material such as metal, there may be a problem of short circuit defects occurring due to a by-product generated during the etching process.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a reactive ion beam etching method having high reliability.

Additional aspects will be set forth in part in the description which follows and, in part, will be apparent from the description, or may be learned by practice of the presented embodiments.

According to an aspect of an example embodiment, an ion beam etching method may include preparing a substrate on which a plurality of magnetic random access memory (MRAM) stacks are provided, performing main etching using ion beam etching such that sidewalls of the plurality of MRAM stacks have a target angle of inclination, and removing a conductive etching by-product redeposited on the sidewalls of the plurality of MRAM stacks during the main etching by performing trim etching using ion beam etching, where the performing the main etching includes performing a first main etching using ion beam etching on the plurality of MRAM stacks at a first incidence angle with respect to an upper surface of the substrate, and after performing the first main etching, performing a second main etching using ion beam etching on the plurality of MRAM stacks at a second incidence angle that is smaller than the first incidence angle.

According to an aspect of an example embodiment, an ion beam etching method may include forming a plurality of stacks on a substrate, each of the plurality of stacks including a lower electrode layer, an upper electrode layer, and at least one dielectric layer between the lower electrode layer and the upper electrode layer, performing main etching using ion beam etching such that sidewalls of the plurality of stacks have a target angle of inclination, and removing a conductive etching by-product redeposited on the sidewalls of the plurality of stacks during the main etching by performing trim etching using ion beam etching, where the performing the main etching includes performing a first main etching using ion beam etching on the plurality of stacks at a first incidence angle with respect to an upper surface of the substrate, and after performing the first main etching, performing a second main etching using ion beam etching on the plurality of stacks at a second incidence angle that is smaller than the first incidence angle.

According to an aspect of an example embodiment, an ion beam etching method may include preparing a substrate on which a plurality of MRAM stacks are provided, performing a first main etching using ion beam etching on the plurality of MRAM stacks at a first incidence angle with respect to an upper surface of the substrate such that sidewalls of the plurality of MRAM stacks have a first angle of inclination, performing a second main etching using ion beam etching on the plurality of MRAM stacks at a second incidence angle that is smaller than the first incidence angle, such that the sidewalls of the plurality of MRAM stacks have a second angle of inclination that is smaller than the first angle of inclination, and removing a conductive etching by-product layer redeposited on the sidewalls of the plurality of MRAM stacks during the first main etching and the second main etching by performing trim etching using ion beam etching, where the conductive etching by-product layer is redeposited on the sidewalls of the plurality of MRAM stacks during the first main etching at a first thickness and during the second main etching at a second thickness that is smaller than the first thickness.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating an ion beam etching device according to one or more embodiments;

FIG. 2 is a flowchart illustrating an ion beam etching method according to one or more embodiments;

FIGS. 3A to 3C are cross-sectional views illustrating main processes of an ion beam etching method according to one or more embodiments;

FIG. 4 is a plan view illustrating a semiconductor memory according to one or more embodiments;

FIG. 5A is a cross-sectional view along line I-I′ of FIG. 4, according to one or more embodiments;

FIG. 5B is a cross-sectional view along line II-II′ of FIG. 4, according to one or more embodiments;

FIGS. 6A to 6D are cross-sectional views illustrating main processes of an ion beam etching method according to one or more embodiments;

FIG. 7 is a graph illustrating a thickness of a redeposited etching by-product layer according to an incidence angle of second main etching, according to one or more embodiments;

FIG. 8 is a graph illustrating a thickness of a redeposited etching by-product layer according to a time ratio of first and second main etching, according to one or more embodiments;

FIG. 9 is a flowchart illustrating an ion beam etching method according to one or more embodiments; and

FIG. 10 is a flowchart illustrating an ion beam etching method according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c

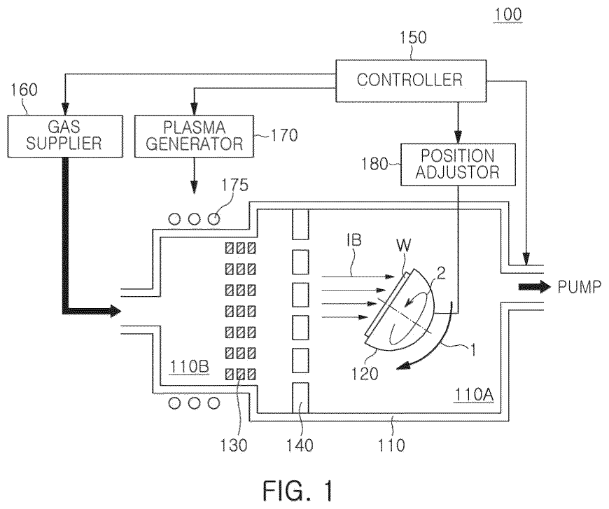

FIG. 1 is a diagram illustrating an ion beam etching device according to one or more embodiments.

Referring to FIG. 1, an ion beam etching device 100 according to one or more embodiments may include a chamber 110 in which a processing chamber 110A and an ion beam generation chamber 110B are separated, a substrate holder 120 disposed in the processing chamber 110A and supporting a substrate W, and a controller 150 controlling an ion beam etching process.

The ion beam generation chamber 110B may be separated from the processing chamber 110A by an ion beam shutter 140. An induction coil 175 may be disposed on an external side wall of the ion beam generation chamber 110B, and a plasma generator 170 may be configured to apply radio frequency (RF) power to the induction coil 175. A gas supplier 160 may supply gas to the ion beam generation chamber 110B, and the RF power applied to the induction coil 175 may generate plasma in the ion beam generation chamber 110B. In one or more embodiments, a gas mixture supplied from the gas supplier 160 may include inert gases and reactive chemicals such as helium (He), neon (Ne), argon (Ar), xenon (Xe), or krypton (Kr).

The ion beam extraction electrode 130 may extract positive ions from the plasma, and may accelerate positive ions in a beam (i.e., an ion beam IB) toward the substrate W. In one or more embodiments, the ion beam extraction electrode 130 may include a plurality of (e.g., three) grid electrodes. The ion beam shutter 140 may be disposed between the ion beam extraction electrode 130 and the substrate holder W. The ion beam shutter 140 may control the ion beam IB to reach the substrate W.

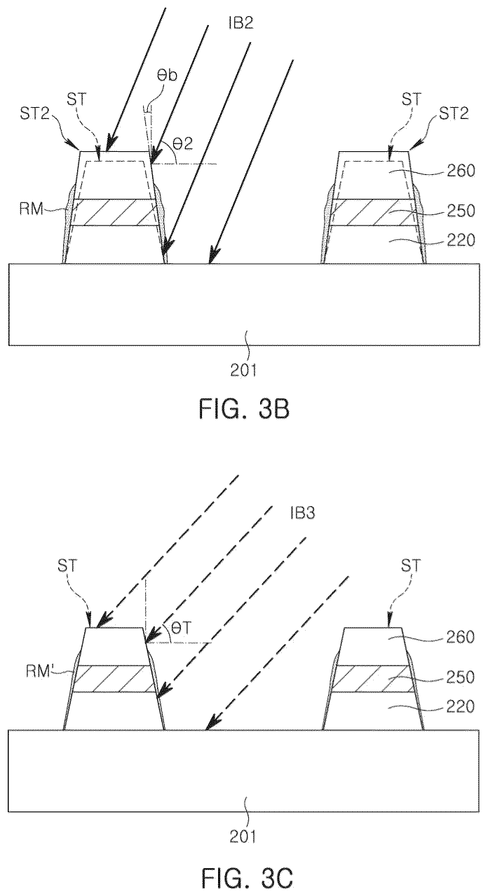

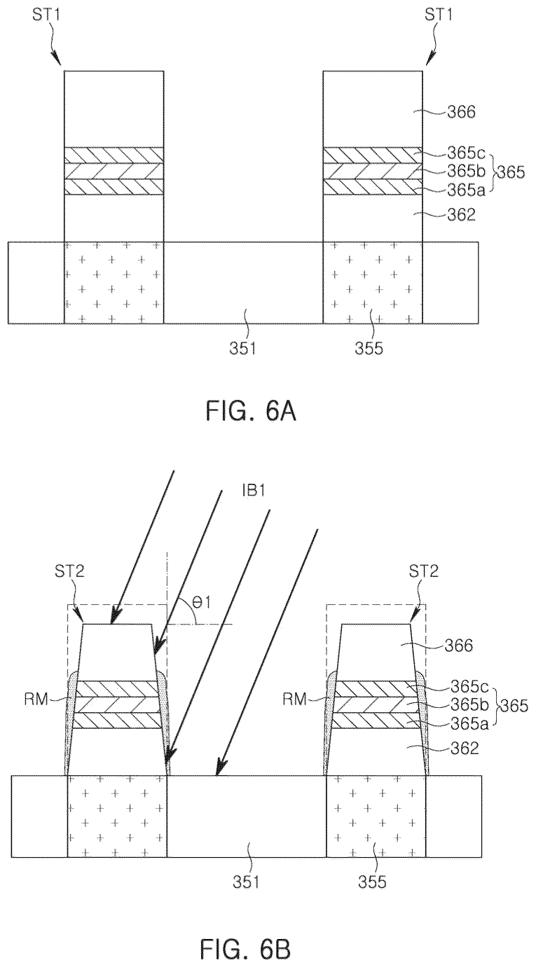

The substrate W may be a semiconductor wafer. A multilayer stack (ST′ in FIG. 3A) constituting a device may be included on the semiconductor wafer. In one or more embodiments, the multilayer stack may include magnetic random access memory (MRAM) stacks (ST′ in FIG. 6A) constituting a plurality of MRAM cells arranged at a constant pitch on the substrate. The substrate W may be attached to the substrate holder 120 in an appropriate manner, such as static electricity or vacuum.

The substrate holder 120 in one or more embodiments may be configured to precisely tilt and rotate by a position adjustor 180. A tilting operation 1 may move the substrate holder 120 about an axis perpendicular to a propagation direction of the ion beam to adjust an incidence angle (e.g., 01 in FIG. 3A) of the ion beam IB propagating through the ion beam shutter 140. In this case, the incidence angle of the ion beam IB may be defined by an angle of the ion beam IB incident on an upper surface of the substrate W. A rotation operation 2 may rotate the substrate holder 120 about an axis perpendicular to the upper surface of the substrate W, such that the ion beam IB is uniformly incident on the upper surface of the substrate W. In one or more embodiments, the position adjustor 180 may be configured to control a position of the substrate holder 120 to adjust an incidence angle implemented in main etching (first and second main etching) and trim etching.

In one or more embodiments, the processing chamber 110A may further include a neutralizer for neutralizing a charge of the ion beam. Additionally, a pump may be connected to the processing chamber 110A to control an internal pressure thereof, and may exhaust reaction materials from the processing chamber 110A.

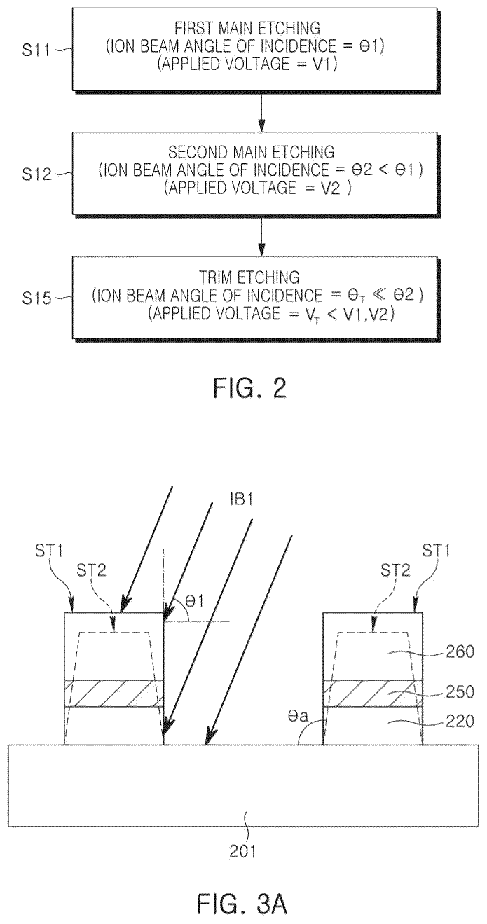

The controller 150 may control a series of etching processes performed in the ion beam etching device 100. In one or more embodiments, the controller 150 may be configured to control the plasma generator 170, the gas supplier 160, and the position adjustor 180. Additionally, the controller 150 may be configured to control the neutralizer and/or the pump. The controller 150 may include one or more memory devices and one or more processors. The controller 150 of one or more embodiments may be configured to perform an ion beam etching process including a plurality of main etching processes and a trim etching process by adjusting an incidence angle of the ion beam IB and an intensity of the ion beam IB. The plurality of main etching processes may provide a method of suppressing accumulation of a conductive etching by-product by etching a sidewall of a plurality of stacks such that a sidewall of a stack structure have a target angle of inclination and lowering an incidence angle of one or more processes. The trim etching may refer to a process of removing a conductive etching by-product redeposited on a sidewall of a plurality of stacks, rather than etching the plurality of stacks themselves. The trim etching may be implemented by lowering an incidence angle and an intensity of the ion beam. In one or more embodiments, the controller 150 may be programmed to perform an etching process according to the process of FIGS. 2, 9, and 10.

FIG. 2 is a flowchart illustrating an ion beam etching method according to one or more embodiments. FIGS. 3A to 3C are cross-sectional views illustrating main processes of an ion beam etching method according to one or more embodiments

An ion beam etching method according to one or more embodiments may be introduced into a process for adjusting a sidewall profile of a plurality of stacks ST1. As illustrated in FIG. 3A, a plurality of stacks ST1 may be arranged at a constant pitch on a substrate 201. In one or more embodiments, the plurality of stacks ST1 may include a lower electrode layer 220, an upper electrode layer 260, and at least one dielectric layer 250 between the lower electrode layer 220 and the upper electrode layer 260. A patterning process for forming the stacks ST1 may be performed by an etching process using a mask pattern corresponding to the plurality of stacks. For example, such a patterning process may be performed by an ion beam etching process.

A main etching process using ion beam etching may be performed such that sidewalls of the plurality of stacks ST1 have a target angle of inclination. The main etching may be performed by rotating the substrate 201 while tilting an ion beam at a specific angle. As described above, such tilting and rotation may be performed by a position adjustor (180 in FIG. 1).

The main etching of one or more embodiments may include a first main etching in operation S11 and a second main etching in operation S12 by changing an incidence angle of the ion beam, to form sidewalls of a plurality of stacks ST2 having a desired profile while reducing a thickness (or an amount) of a conductive etching by-product (RM in FIG. 3B or RM′ in FIG. 3C) redeposited on the sidewalls of the stacks ST2.

First, as illustrated in FIG. 3A, the first main etching of operation S11 may including etching a plurality of stacks ST1 using a first ion beam IB1 at a first incidence angle θ1. In the first main etching, the plurality of stacks ST1 may be etched to approximate a desired side surface profile (e.g., the dotted line structure shown in FIG. 3A), to form stacks ST2 having a predetermined angle of inclination θa. For example, the first incidence angle θ1 of the first main etching may be in a range of 50° to 80°. The first ion beam IB1 used for the first main etching may have a sufficient intensity to partially etch the plurality of stacks ST1. For example, the intensity of the first ion beam IB1 may be in a range of about 500 V to about 5000 V.

An etching by-product RM may be generated during the first main etching, and the etching by-product RM may be redeposited on side surfaces of the stacks ST2 (see FIG. 3B). The etching by-product RM may be a conductive etching by-product containing an element of a lower electrode layer 220 and an element of an upper electrode layer 260. The conductive etching by-product RM may be widely deposited on a side surface of a dielectric layer 250 to cause an unwanted short circuit. Additionally, in one or more embodiments, unnecessary inclined portions may be additionally generated in lower portions of the sidewalls of the stacks ST2. Therefore, since removal of the redeposited conductive etching by-product RM may be required, and may not be sufficiently removed in a subsequent trim etching, a second main etching in operation S12 may be performed to suppress redepositing the conductive etching by-product RM in the first main etching process.

Subsequently, as illustrated in FIG. 3B, a second main etching in operation S12 may include etching the plurality of stacks ST2 with a second ion beam IB2 adjusted to have a second incidence angle θ2 that is smaller than the first incidence angle θ1. In the second main etching, the plurality of stacks ST2 may be additionally etched to form stacks ST having a desired side surface profile (e.g., the dotted line in FIG. 3B). For example, the second incidence angle θ2 of the second main etching may be in a range of 50° to 80°, but may be smaller than the first incidence angle θ1. In one or more embodiments, the second incidence angle θ2 may be smaller than the first incidence angle θ1 by a range of 2° to 10°. Since a sidewall angle of inclination Ob of the stacks may be changed during the main etching process, an incidence angle on the side surfaces of the stacks ST2 may be further reduced even when ion beams having the same incidence angle are applied.

The second ion beam IB2 may have a sufficient intensity, and, even during the second main etching process, may be incident at a relatively low angle with respect to the side surfaces of the stacks ST2 while changing profiles of the stacks (changing the profile from ST2 to ST). Therefore, the conductive etching by-product RM redeposited on the sides of the stacks ST2 may be removed, or occurrence of an additional conductive etching by-product may be reduced. An intensity of the second ion beam IB2 may range from about 500 V to about 5000 V, similar to an intensity of the first ion beam IB1, and even when slightly reduced or changed, may be less than the intensity of the ion beam of the first main etching by 10% or less.

As a result of the second main etching, as illustrated in FIG. 3C, a conductive etching by-product RM′ remaining on the sidewalls of the stacks ST, before trim etching in operation S15 in a low energy manner, may remain only at a sufficiently thin thickness that may be sufficiently removed. The trim etching in operation S15 may be performed as a process for removing the conductive etching by-product RM′ redeposited on the sidewalls of the stacks ST. A third ion beam IB3 used for the trim etching may be incident at an angle θT that may be lower than the angles of incidence θ1 and θ2 of the main etching. For example, a trim incidence angle θT may be in a range of 30° to 50°.

Additionally, the trim etching may use the third ion beam IB3 having an intensity, such that the plurality of stacks ST are not substantially etched. For example, the intensity of the third ion beam may be in a range of about 50 V to about 400 V.

The ion beam etching process may be beneficially used in a process of manufacturing semiconductor devices such as MRAM devices. Unlike dynamic RAM (DRAM), the MRAM may be a type of resistive memory that may be based on a change in resistance of a magnetic tunnel junction (MTJ) layer. Memory cells of the MRAM may include an MRAM stack respectively including a magnetic tunnel barrier layer, and such an MRAM stack may be fabricated by a reactive ion beam etching process according to one or more embodiments.

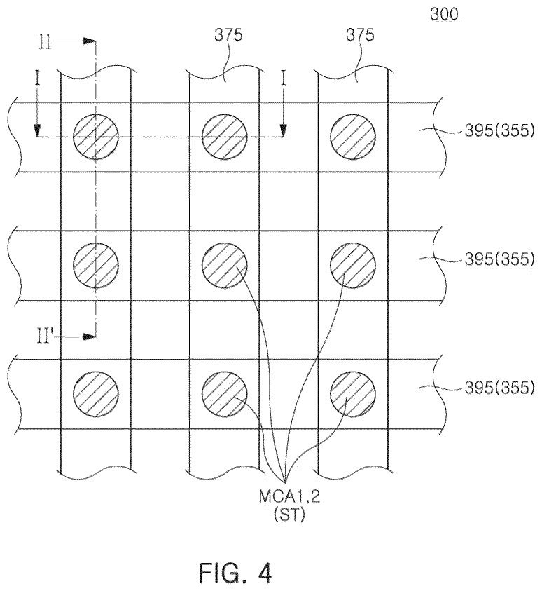

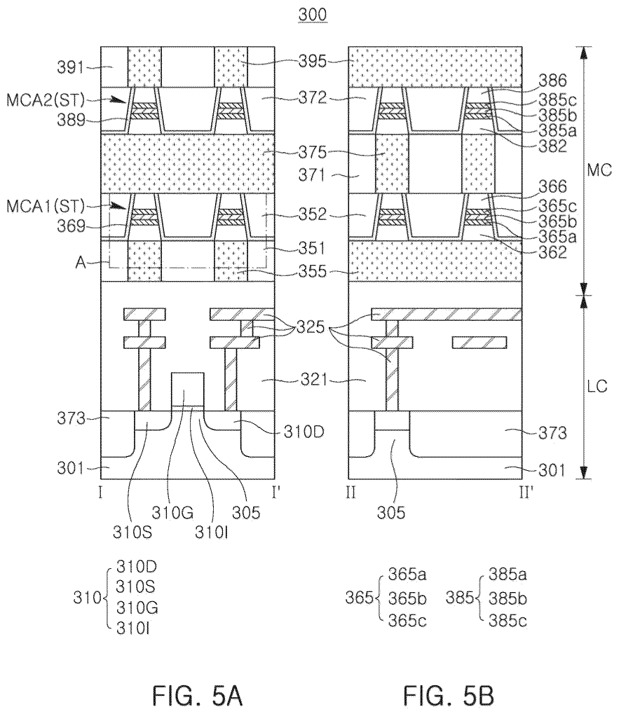

FIG. 4 is a plan view illustrating a semiconductor memory according to one or more embodiments. FIG. 5A is a cross-sectional view along line I-I′ of FIG. 4, according to one or more embodiments. FIG. 5B is a cross-sectional view along line II-II′ of FIG. 4, according to one or more embodiments

Referring to FIGS. 4, 5A and 5B 5, a semiconductor device 300 according to one or more embodiments may include a lower structure LC, a first conductive line 355 on the lower structure LC, first memory cell structures MCA1 on the first conductive line 355, a second conductive line 375 on the first memory cell structures MCA1, second memory cell structures MCA2 on the second conductive line 375, and a third conductive line 395 on the second memory cell structures MCA2.

The lower structure LC may include a semiconductor substrate 301, a circuit device 310 on the semiconductor substrate 301, a circuit interconnection 325 electrically connected to the circuit device 310 on the semiconductor substrate 301, and a lower insulating structure 321 covering the circuit device 310 and the circuit interconnection 325 on the semiconductor substrate 301. The circuit device 310 may include a transistor including a gate electrode 310G disposed on an active region 305 defined by a device isolation layer 373 on the semiconductor substrate 301, a gate insulating film 310I between the active region 305 and the gate electrode 310G, and source/drain regions 310S and 310D disposed in the active region 305 on both sides of the gate electrode 310G.

The semiconductor device 300 according to one or more embodiments may further include a first insulating pattern 351 covering a side surface of the first conductive line 355, a second insulating pattern 371 covering a side surface of the second conductive line 375, and a third insulating pattern 391 covering a side surface of the third conductive line 395.

Additionally, the semiconductor device 300 may further include a first gap-fill insulating pattern 352 surrounding a side surface of the first memory cell structures MCA1, a first insulating protective layer 369 between the first gap-fill insulating pattern 352 and the first memory cell structure MCA1, a second gap-fill insulating pattern 372 surrounding a side surface of the second memory cell structures MCA2, and a second insulating protective layer 389 between the second gap-fill insulating pattern 372 and the second memory cell structures MCA2.

The first insulating protective layer 369 may extend from between the first gap-fill insulating pattern 352 and the first memory cell structure MCA1 along a lower surface of the first gap-fill insulating pattern 352. Similarly, the second insulating protective layer 389 may extend from between the second gap-fill insulating pattern 372 and the second memory cell structures MCA2 to cover a lower surface of the second gap-fill insulating pattern 372. For example, the first and second insulating protective layers 369 and 389 may include at least one of SiN, SiO₂, SION, SiBN, SiCN, SiOCN, Al₂O₃, AlN, and AlON, respectively. Additionally, each of the first and second gap-fill insulating patterns 352 and 372 may include at least one of SiN, SiON, SiC, SiCN, SiOC, SiOCN, SiO₂, and Al₂O₃.

The first and second memory cell structures MCA1 and MCA2 may include a MRAM stack ST. The MRAM stack ST may include lower electrode layers 362 and 382, upper electrode layers 366 and 386, and MTJ stacks 365 and 385 disposed between the lower electrode layers 362 and 382, and the upper electrode layers 366 and 386. The MTJ stacks 365 and 385 according to one or more embodiments may include first magnetic layers 365a and 385a used as reference elements, second magnetic layers 365c and 385c used as storage elements, and magnetic tunnel barrier layers 365b and 385b between the first and second magnetic layers 365a and 365c and 385a and 385c, respectively.

For example, the lower electrode layers 362 and 382 and the upper electrode layers 366 and 386 may include an electrically conductive material such as Ta, Ti, W, TiN, TaN, Pt, or Ru. In one or more embodiments, the lower electrode layers 362 and 382 and the upper electrode layers 366 and 386 may include TiN.

The first magnetic layers 365a and 385a and the second magnetic layers 365c and 385c may include cobalt (Co), nickel (Ni), iron (Fe), or combinations thereof. For example, the first magnetic layers 365a and 385a and the second magnetic layers 365c and 385c may further include a non-magnetic material such as boron (B), titanium (Ti), zirconium (Zr), hafnium (Hf), vanadium (V), niobium (Nb), tantalum (Ta), chromium (Cr), molybdenum (Mo), or tungsten (W). In one or more embodiments, the first magnetic layers 365a and 385a and the second magnetic layers 365c and 385c may include a plurality of magnetic layers.

The magnetic tunnel barrier layers 365b and 385b may include a non-magnetic insulating material. For example, the magnetic tunnel barrier layers 365b and 385b may include magnesium oxide (MgO). Upper and lower regions of the MTJ stacks 365 and 385 may have lower electrode layers 362 and 382 and upper electrode layers 366 and 386, as well as first and second magnetic layers 365a, 385a, 365c, and 385c. In an ion beam etching process, an etching by-product may be a conductive material.

Therefore, after the ion beam etching process, when a conductive etching by-product remains on the MgO and side surfaces of the magnetic tunnel barrier layers 365b and 385b, a short circuit may occur. In addition, since the etching by-product generates a sagging inclined portion in a lower portion of a sidewall of the MRAM stack ST, it may be difficult to achieve a target profile. To solve this problem, an ion beam etching process according to one or more embodiments may include a main etching process in which an incidence angle of an ion beam is adjusted. Specifically, the ion beam etching process may sequentially use main etching (using a high-energy beam) to adjust a sidewall profile, and trim etching (using a low-energy beam) to remove a conductive etching by-product. To reduce an etching by-product redeposited on a surface, a multi-step main etching process changing an incidence angle may be implemented.

FIGS. 6A to 6D are cross-sectional views illustrating main processes of an ion beam etching method according to one or more embodiments. Process diagrams of FIGS. 6A to 6D are enlarged cross-sectional views of portion “A” of FIG. 5A, and may be understood as a portion of processes of manufacturing first memory cell structures MCA1. Additionally, an ion beam etching process, similar thereto, may be used to provide processes of manufacturing second memory cell structures MCA2.

First, referring to FIG. 6A, a substrate 351/355 on which a plurality of MRAM stacks ST1 are arranged may be prepared. The plurality of MRAM stacks ST1 may be a structure obtained by anisotropically etching (e.g., by reactive ion etching) stacks having a layered structure using a mask pattern. The plurality of MRAM stacks ST1 may have a substantially vertical sidewall.

As previously described, the plurality of MRAM stacks ST1 may include a lower electrode layer 362, an upper electrode layer 366, and an MTJ stack 365 disposed between the lower electrode layer 362 and the upper electrode layers 366. The MTJ stack 365 may include a first magnetic layer 365a, a second magnetic layer 365c, and a magnetic tunnel barrier layer 365b between the first and second magnetic layers 365a and 365c. In this case, the magnetic tunnel barrier layer 365b may include a non-magnetic insulating material.

Next, referring to FIG. 6B, a first main etching may be performed using a first ion beam IB1 such that sidewalls of the plurality of MRAM stacks are etched into the structure corresponding to ST2 and to have a target angle of inclination.

In the first main etching, the first main etching may be performed by applying the first ion beam IB1 to the plurality of MRAM stacks at a first incidence angle θ1 with respect to an upper surface of a substrate 351/355. For example, the first incidence angle θ1 of the first main etching may be in a range of 50° to 80°. The first ion beam IB1 may have a sufficient intensity to etch a plurality of stacks ST2. For example, an intensity of the first ion beam IB1 may be in a range of about 500 V to about 5000 V. During the first main etching, a conductive etching by-product RM may be generated, and the conductive etching by-product RM may be redeposited on side surfaces of the stacks ST2. The conductive etching by-product RM may be a by-product of lower electrode layers 220, upper electrode layers 260, and the like, and, may include, for example, tungsten W, titanium (Ti), tantalum (Ta), titanium nitride (TiN), tantalum nitride (TaN), cobalt (Co), nickel (Ni), iron (Fe), platinum (Pt), ruthenium (Ru), or a combination thereof.

Next, referring to FIG. 6C, second main etching may be performed on the plurality of MRAM stacks (ST2→ST) by using a second ion beam IB2 at a second incidence angle θ2, smaller than the first incidence angle θ1.

In the second main etching, the second ion beam IB2 may be maintained at a sufficient intensity such that an angle of inclination of sidewalls of the plurality of MRAM stacks may be adjusted, and the stacks may be etched to form the structure ST from the structure ST2. The second incidence angle θ2 may be relatively low when using the second ion beam IB2 such that the redeposited conductive etching by-product RM may be partially removed and additional redeposition may be suppressed.

For example, the second incidence angle θ2 of the second main etching may be in a range of 50° to 80°, but may be smaller than the first incidence angle θ1. In one or more embodiments, the second incidence angle θ2 may be smaller than the first incidence angle θ1 by a range of 2° to 10°. An intensity of the second ion beam IB2 may range from about 500 V to about 5000 V, similar to an intensity of the first ion beam IB1, and, even when slightly reduced or changed, may be different from the intensity of the first ion beam by 10% or less. After the second main etching, as illustrated in FIG. 6C, a conductive etching by-product RM remaining on a sidewall of an MRAM stack ST may remain at a sufficiently thin thickness that may be sufficiently removed by a subsequent process.

Next, referring to FIG. 6D, trim etching may be performed using a third ion beam IB3 to remove the conductive etching by-product RM redeposited on the sidewalls of the plurality of MRAM stacks ST.

The trim etching may be used as a process to remove the conductive etching by-product RM redeposited on the sidewalls of the stacks ST. The trim etching may use the third ion beam IB3 at an intensity that does not substantially etch the plurality of stacks ST. For example, the intensity of the third ion beam IB3 may be in a range of about 50 V to about 400 V. Additionally, the third ion beam IB3 may be incident at an angle θT that may be lower than the angles of incidence θ1 and θ2 of the main etching. For example, the trim incidence angle θT may be in a range of 30° to 50°. After performing the trim etching, an insulating protective layer 369 may be conformally formed on the sidewalls of the plurality of MRAM stacks ST.

In one or more embodiments, when performing processes for suppressing a conductive etching by-product by separate first and second main etching, a change in thickness of the conductive etching by-product layer redeposited on a side surface of a MTJ layer (e.g., an MgO layer), depending on an incidence angle and etching time conditions, were confirmed.

### <Incidence Angle Change Conditions for Main Etching>

In the example embodiments of 1 to 9 of Table 1 below, first and second main etching processes according to one or more embodiments were performed for the same time (104 seconds, respectively), but different angles of incidence. After the main etching, a thickness of an etching by-product layer on a side surface of a magnetic tunnel bonding layer was measured. Additionally, in a comparative example, after a single main etching process (at the same incidence angle) was performed for the same etching time (208 seconds) as the example embodiments, a thickness of a conductive etching by-product layer on a side surface of a magnetic tunnel bonding layer was measured. In this case, an ion beam used in each etching process had the same intensity (1000 V).

TABLE 1

| | First Main Etching | | Second Main Etching | |
|---|---|---|---|---|
| | Incidence | | Incidence | |
| Example | angle (°) | Time (sec) | angle (°) | Time (sec) |
| Comparative Ex. (Ref). | 60 | 104 | 60 | 104 |
| Ex. Embodiment. 1 | | | 59 | |
| Ex. Embodiment. 2 | | | 58 | |
| Ex. Embodiment. 3 | | | 57 | |
| Ex. Embodiment. 4 | | | 56 | |
| Ex. Embodiment. 5 | | | 55 | |
| Ex. Embodiment. 6 | | | 52 | |
| Ex. Embodiment. 7 | | | 50 | |
| Ex. Embodiment. 8 | | | 47 | |
| Ex. Embodiment. 9 | | | 45 | |

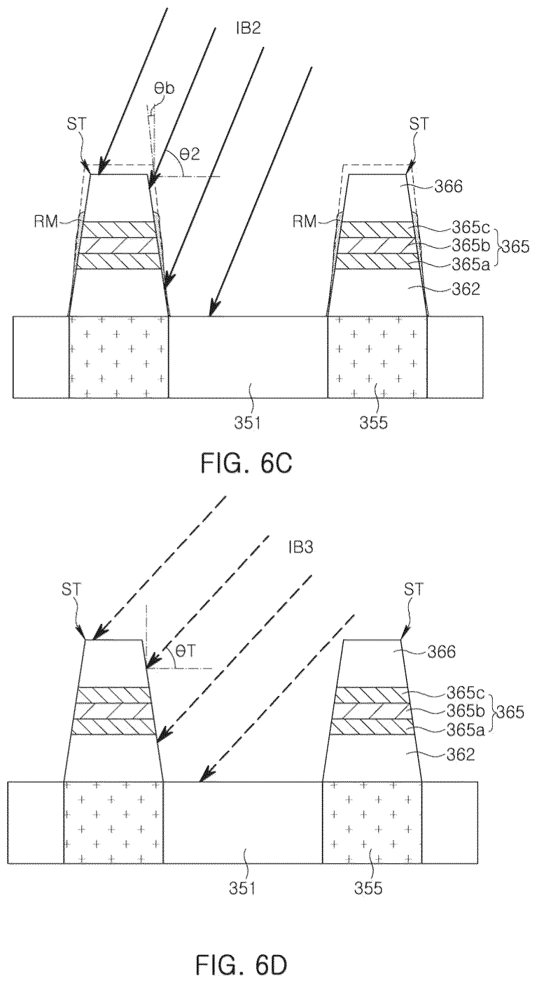

In the comparative example (Ref.) and example embodiments 1 to 9, described above, thicknesses of the conductive etching by-product layers redeposited after the main etching were measured and illustrated in the graph of FIG. 7.

FIG. 7 is a graph illustrating a thickness of a redeposited etching by-product layer according to an incidence angle of second main etching, according to one or more embodiments. Referring to FIG. 7, it may be confirmed that thicknesses of etching by-product layers when angles of incidence of the ion beam of the second main etching were 50° to 58° were reduced, compared to the comparative example. In particular, it may be confirmed that thicknesses of etching by-product layers when angles of incidence of the second main etching were 52° to 57° were significantly reduced. In general, an effect of reducing a thickness of an etching by-product layer may be expected when a second incidence angle is smaller than a first incidence angle by a range of 2° to 10°.

### <Time Ratio Conditions for Main Etching>

First and second main etching processes according to one or more embodiments were performed for the same time (208 seconds) at angles of incidence of 60° and 56°, respectively, but time ratios of the first and second main etching processes were changed as illustrated in Table 2 below. In this case, an ion beam used in each etching process had the same intensity (1000 V).

TABLE 2

| | First Main Etching | | Second Main Etching | |
|---|---|---|---|---|
| | Incidence | | Incidence | |
| Example | angle (°) | Time (sec) | angle (°) | Time (sec) |
| Ex. Embodiment. a | 60 | 188 | 56 | 20 |
| Ex. Embodiment. b | | 168 | | 40 |
| Ex. Embodiment. c | | 148 | | 60 |
| Ex. Embodiment. d | | 128 | | 80 |
| Ex. Embodiment. e | | 108 | | 100 |
| Ex. Embodiment. f | | 88 | | 120 |
| Ex. Embodiment. g | | 68 | | 140 |
| Ex. Embodiment. h | | 48 | | 160 |
| Ex. Embodiment. i | | 28 | | 180 |
| Ex. Embodiment. j | | 8 | | 200 |

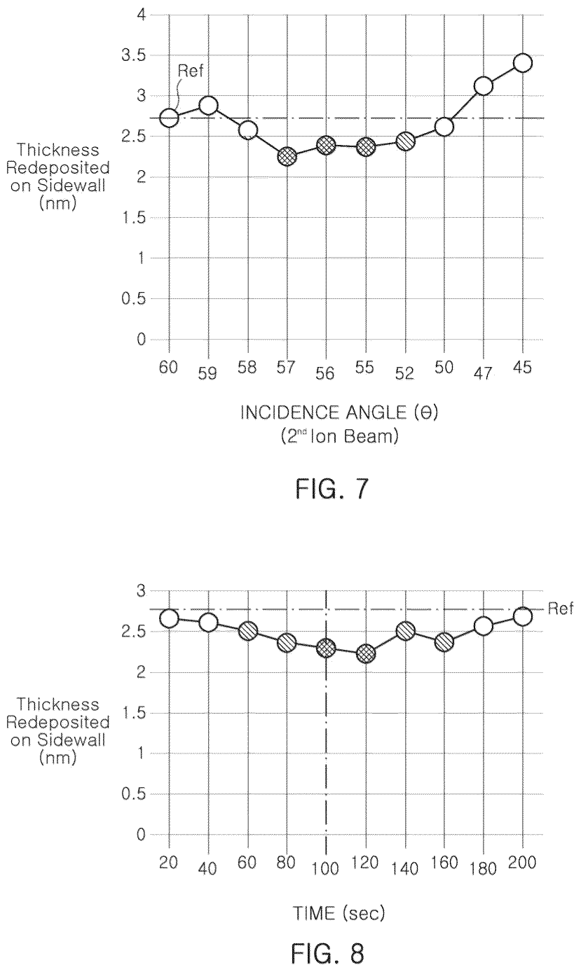

FIG. 8 is a graph illustrating a thickness of a redeposited etching by-product layer according to a time ratio of first and second main etching, according to one or more embodiments. In example embodiments a to j described above, thicknesses of conductive etching by-product layers redeposited after the main etching were measured and illustrated in the graph of FIG. 8.

Referring to FIG. 8, results of example embodiments a to j were generally lower than the etching by-product thickness in the comparative example, regardless of the time ratio of the second main etching. In particular, in results of example embodiments c to h, thicknesses of etching by-products were improved to 2.5 nm or less, and in results of example embodiments e and f, thicknesses of etching by-products were reduced by the greatest magnitude. In general, time ratios of the first and second main etching may be in a range of 1:1 to 1:2.

A method for changing the incidence angle in the main etching may be implemented in various manners.

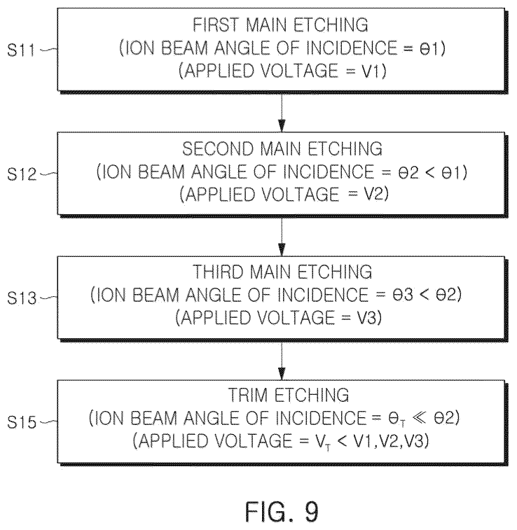

FIG. 9 is a flowchart illustrating an ion beam etching method according to one or more embodiments.

Referring to FIG. 9, first main etching using an ion beam may be performed on a plurality of MRAM stacks in operation S11.

In the first main etching, a first incidence angle θ1 of the ion beam and applied voltage V1 may have sufficient conditions for etching a plurality of stacks ST2. For example, the incidence angle θ1 of the first main etching may be in a range of 50° to 80°. An intensity of the ion beam for the first main etching may be in a range of about 500 V to about 5000 V.

Subsequently, after the first main etching of operation S11, a second main etching using an ion beam may be performed on the plurality of MRAM stacks in operation S12.

In the second main etching, the ion beam may have a second incidence angle θ2 that may be smaller than the first incidence angle θ1, and energy of the ion beam may be maintained on a level, equal to or similar to the intensity of the ion beam of the first main etching. For example, the second incidence angle θ2 of the second main etching may be in a range of 50° to 80°, but may be smaller than the first incidence angle θ1. In one or more embodiments, the second incidence angle θ2 may be smaller than the first incidence angle θ1 by a range of 2° to 10°. An intensity of the ion beam of the second main etching may be in a range of about 500 V to about 5000 V, similar to the intensity of the ion beam of the first main etching, and, even when slightly reduced or altered, may be different from the intensity of the ion beam of the first main etching by 10% or less.

Next, after the second main etching in operation S12, a third main etching using an ion beam may be performed on the plurality of MRAM stacks in operation S13.

In the third main etching, the ion beam may have a third incidence angle θ3 that may be smaller than the second incidence angle θ2, and energy of the ion beam may be maintained on a level, equal to or similar to an intensity of the ion beam of the first and second main etchings, respectively. For example, the third incidence angle θ3 may be in a range of 50° to 80°, but may be smaller than the first incidence angle θ1. In one or more embodiments, the third incidence angle θ3 may be smaller than the first incidence angle θ1 by a range of 2° to 10°. An intensity of the ion beam of the third main etching may be in a range of about 500 V to about 5000 V, similar to the intensity of the ion beam of the other main etching, and, even when slightly reduced or altered, may be different from the intensity of the ion beam of the other main etching by 10% or less.

Next, trim etching using a low-energy ion beam may be performed to remove a conductive etching by-product redeposited on sidewalls of the plurality of MRAM stacks in operation S15.

In the trim etching, the ion beam may have an intensity that does not substantially etch the plurality of stacks ST. For example, the intensity of the ion beam for the trim etching may be in a range of about 50 V to about 400 V. Additionally, the ion beam of the trim etching may be incident at an angle θT that may be lower than the angles of incidence θ1 and θ2 of the main etching. For example, an incidence angle θT may be 30° to 50°

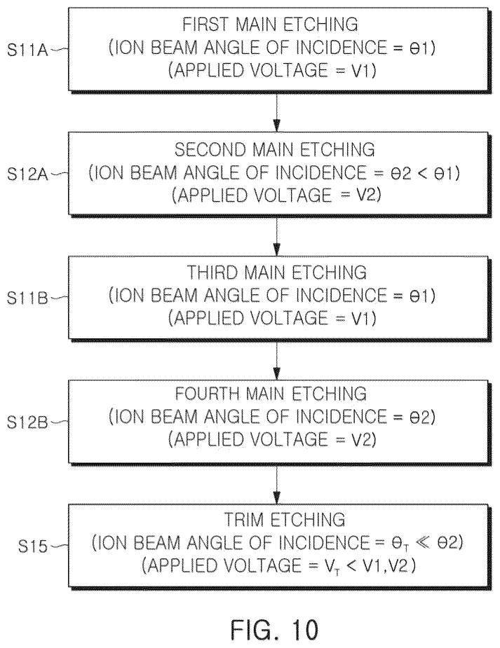

FIG. 10 is a flowchart illustrating an ion beam etching method according to one or more embodiments. Referring to FIG. 10, similar to the processes of those described above, a first main etching using an ion beam may be performed on a plurality of MRAM stacks in operation S11A, and then a second main etching using an ion beam may be performed on the plurality of MRAM stacks in operation S12A.

Next, similar to the first main etching and the second main etching, a third main etching of operation S11B and a fourth main etching of operation S12B may be repeatedly performed.

Similar to the first main etching, a third incidence angle θ1 of the third main etching may be in a range of 50° to 80°. An intensity of an ion beam for the third main etching may be in a range of about 500 V to about 5000 V. Additionally, similar to the second main etching, an ion beam for the fourth main etching may have a fourth incidence angle θ2 that may be smaller than the third incidence angle θ1, and energy of the ion beam may be maintained on a level, equal to or similar to an intensity of the ion beam of the first main etching. For example, the fourth incidence angle θ2 of the fourth main etching may be in a range of 50° to 80°, but may be smaller than the third incidence angle θ1. In one or more embodiments, the fourth incidence angle θ2 may be smaller than the third incidence angle θ1 by a range of 2° to 10°. An intensity of an ion beam for the fourth main etching may be in a range of about 500 V to about 5000 V, similar to the intensity of the ion beam of the third main etching, and, even when slightly reduced or changed, may be different from the intensity of the ion beam of the third main etching by 10% or less.

Next, trim etching using a low-energy ion beam may be performed to remove a conductive etching by-product redeposited on sidewalls of the plurality of MRAM stacks in operation S15.

In the trim etching, the ion beam may have an intensity that does not substantially etch the plurality of stacks ST. For example, the intensity of the ion beam for the trim etching may be in a range of about 50 V to about 400 V. Additionally, the ion beam of the trim etching may be incident at an angle θT that may be lower than the angles of incidence θ1 and θ2 of the main etching. For example, an incidence angle θT may be in a range of 30° to 50°.

According to one or more embodiments, in a process of applying main etching such that a sidewall of an MRAM stack constituting a memory cell has a target profile (i.e., a target angle of inclination), an incidence angle of an ion beam may be adjusted to partially remove a conductive etching by-product redeposited during the etching process, and thus the conductive etching by-product remaining and thinned during trim etching may be easily removed.

At least one of the devices, units, components, modules, units, or the like represented by a block or an equivalent indication in the above embodiments including, but not limited to, FIG. 1, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An ion beam etching method comprising:
preparing a substrate on which a plurality of magnetic random access memory (MRAM) stacks are provided;
performing a main etching using ion beam etching such that sidewalls of the plurality of MRAM stacks have a target angle of inclination; and
removing a conductive etching by-product redeposited on the sidewalls of the plurality of MRAM stacks during the main etching by performing trim etching using ion beam etching,
wherein the performing the main etching comprises:
performing a first main etching using ion beam etching on the plurality of MRAM stacks at a first incidence angle with respect to an upper surface of the substrate; and
after performing the first main etching, performing a second main etching using ion beam etching on the plurality of MRAM stacks at a second incidence angle that is smaller than the first incidence angle.

2. The ion beam etching method of claim 1, wherein the first incidence angle is in a range of 50° to 80°,
wherein the trim etching is performed at a third incidence angle, and
wherein the third incidence angle is in a range of 30° to 50°.

3. The ion beam etching method of claim 2, wherein the second incidence angle is smaller than the first incidence angle by a range of 2° to 10°.

4. The ion beam etching method of claim 1, wherein a first ion beam intensity of the first main etching and a second ion beam intensity of the second main etching are in a range of about 500 V to about 10000 V, and
wherein a third ion beam intensity of the trim etching is in a range of about 50 V to about 400 V.

5. The ion beam etching method of claim 1, wherein an ion beam of the trim etching has an intensity such that each of the plurality of MRAM stacks is not substantially etched.

6. The ion beam etching method of claim 1, wherein a first ion beam intensity of the first main etching is up to 10% less than a second ion beam intensity of the second main etching.

7. The ion beam etching method of claim 1, wherein the performing the second main etching comprises partially removing the redeposited conductive etching by-product.

8. The ion beam etching method of claim 1, wherein a time ratio of an amount of time of the first main etching to an amount of time of the second main etching is in a range of 1:1 to 1:2.

9. The ion beam etching method of claim 1, wherein the performing the main etching further comprises, after the performing the second main etching, performing a third main etching using ion beam etching on the plurality of MRAM stacks at a third incidence angle that is smaller than the second incidence angle.

10. The ion beam etching method of claim 1, wherein the performing the main etching further comprises:
after the performing the second main etching, performing a third main etching using ion beam etching on the plurality of MRAM stacks at a third incidence angle that is greater than the second incidence angle; and
after the performing the third main etching, performing a fourth main etching using ion beam etching on the plurality of MRAM stacks at a fourth incidence angle that is smaller than the third incidence angle.

11. The ion beam etching method of claim 1, wherein the plurality of MRAM stacks comprise a lower electrode layer, an upper electrode layer, and a magnetic tunnel junction (MTJ) stack between the lower electrode layer and the upper electrode layer.

12. The ion beam etching method of claim 11, wherein the MTJ stack comprises a first magnetic layer, a second magnetic layer, and a magnetic tunnel barrier layer between the first magnetic layer and the second magnetic layer, and
wherein the magnetic tunnel barrier layer comprises a non-magnetic insulating material.

13. The ion beam etching method of claim 1, wherein the redeposited conductive etching by-product comprises at least one of tungsten W, titanium (Ti), tantalum (Ta), titanium nitride (TiN), tantalum nitride (TaN), cobalt (Co), nickel (Ni), iron (Fe), platinum (Pt), ruthenium (Ru), and a combination thereof.

14. The ion beam etching method of claim 1, further comprising, after the removing the conductive etching by-product redeposited on the sidewalls of the plurality of MRAM stacks, forming an insulating protective layer on the sidewalls of the plurality of MRAM stacks.

15. An ion beam etching method comprising:
forming a plurality of stacks on a substrate, each of the plurality of stacks comprising a lower electrode layer, an upper electrode layer, and at least one dielectric layer between the lower electrode layer and the upper electrode layer;
performing a main etching using ion beam etching such that sidewalls of the plurality of stacks have a target angle of inclination; and
removing a conductive etching by-product redeposited on the sidewalls of the plurality of stacks during the main etching by performing trim etching using ion beam etching,
wherein the performing the main etching comprises:
performing a first main etching using ion beam etching on the plurality of stacks at a first incidence angle with respect to an upper surface of the substrate; and
after performing the first main etching, performing a second main etching using ion beam etching on the plurality of stacks at a second incidence angle that is smaller than the first incidence angle.

16. The ion beam etching method of claim 15, wherein the first incidence angle is in a range of 50° to 80°, and
wherein the second incidence angle is in a range of 2° to 10° smaller than the first incidence angle.

17. The ion beam etching method of claim 16, wherein the trim etching is performed at a third incidence angle, and
wherein the third incidence angle is in a range of 30° to 50°.

18. The ion beam etching method of claim 15, wherein a first ion beam intensity of the first main etching and a second ion beam intensity of the second main etching are in a range of about 500 V to about 5000 V, and
wherein a third ion beam intensity of the trim etching is in a range of about 50 V to about 400 V.

19. An ion beam etching method comprising:
preparing a substrate on which a plurality of magnetic random access memory (MRAM) stacks are provided;
performing a first main etching using ion beam etching on the plurality of MRAM stacks at a first incidence angle with respect to an upper surface of the substrate such that sidewalls of the plurality of MRAM stacks have a first angle of inclination;
performing a second main etching using ion beam etching on the plurality of MRAM stacks at a second incidence angle that is smaller than the first incidence angle, such that the sidewalls of the plurality of MRAM stacks have a second angle of inclination that is smaller than the first angle of inclination; and
removing a conductive etching by-product layer redeposited on the sidewalls of the plurality of MRAM stacks during the first main etching and the second main etching by performing trim etching using ion beam etching,
wherein the conductive etching by-product layer is redeposited on the sidewalls of the plurality of MRAM stacks during the first main etching at a first thickness and during the second main etching at a second thickness that is smaller than the first thickness.

20. The ion beam etching method of claim 19, wherein the first incidence angle is in a range of 50° to 80°,
wherein the second incidence angle is smaller than the first incidence angle by a range of 2° to 10°,
wherein the trim etching is performed at a third incidence angle; and
wherein the third incidence angle for the trim etching is in a range of 30° to 50°.
